(19) United States
(12) Patent Application Publication
(10) Pub. No.: US 2011/0076422 A1
(43) Pub. Date: Mar. 31, 2011

(54) CURVED MICROWAVE PLASMA LINE SOURCE FOR COATING OF THREE-DIMENSIONAL SUBSTRATES

(75) Inventor: Michael W. Stowell, Loveland, CO (US)

(73) Assignee: Applied Materials, Inc., Santa Clara, CA (US)

(21) Appl. No.: 12/833,524

(22) Filed: Jul. 9, 2010

Related U.S. Application Data
(63) Continuation-in-part of application No. PCT/US2008/052383, filed on Jan. 30, 2008.
(60) Provisional application No. 61/224,224, filed on Jul. 9, 2009.
(60) Provisional application No. 61/224,234, filed on Jul. 9, 2009.
(60) Provisional application No. 61/224,371, filed on Jul. 9, 2009.
(60) Provisional application No. 61/224,245, filed on Jul. 9, 2009.

(51) Int. Cl. H05H 1/30; C23C 16/511

(52) U.S. Cl. 427/575; 118/723 AN

(57) ABSTRACT

Deposition system and methods for dynamic and static coatings are provided. A deposition system for dynamic coating includes a processing chamber, a non-linear coaxial microwave source, and a substrate support member disposed inside the processing chamber for holding a non-planar substrate. The substrate has a first contour along a first direction and a second contour along a second direction orthogonal to the first direction. The deposition system further includes a carrier gas line for providing a flow of sputtering agents inside the processing chamber and a feedstock gas line for providing a flow of precursor gases. The deposition system for static coating includes a substrate support member disposed inside the processing chamber for holding a non-planar substrate and an array of curved coaxial microwave sources within the processing chamber. The curved coaxial microwave sources are spaced along the second direction to cover the substrate.

### CROSS-REFERENCES TO RELATED APPLICATIONS

This patent application is a non-provisional of and claims the benefit of U.S. Provisional Patent Application No. 61/224,224, entitled “High Efficiency Low Energy Microwave Ion/Electron Source,” filed Jul. 9, 2009, the entire disclosures of which are incorporated herein by reference for all purposes.

This patent application is a non-provisional of and claims the benefit of U.S. Provisional Patent Application No. 61/224,234, entitled “Curved Surface Wave Fired Plasma Line for Coating of 3 Dimensional Substrates,” filed Jul. 9, 2009, the entire disclosures of which are incorporated herein by reference for all purposes.

This patent application is a non-provisional of and claims the benefit of U.S. Provisional Patent Application No. 61/224,371, entitled “Simultaneous Vertical Deposition of Plasma Displays Layers,” filed Jul. 9, 2009, the entire disclosures of which are incorporated herein by reference for all purposes.

This patent application is a non-provisional of and claims the benefit of U.S. Provisional Patent Application No. 61/224,245, entitled “Microwave Linear Deposition of Plasma Display Protection Layers,” filed Jul. 9, 2009, the entire disclosures of which are incorporated herein by reference for all purposes.

This patent application is a continuation-in-part application of International Application No. PCT/US2008/052383, entitled “System and Method for Microwave Plasma Species Source,” filed 30 Jan. 2008, the entire disclosures of which are incorporated herein by reference for all purposes.

### BACKGROUND OF THE INVENTION

Typical applications of coaxial plasma line sources use an array of linear antenna and tubes that are arranged in parallel with a half wavelength spacing between two of the tubes. This arrangement may be used for coatings over substrate with a simple geometry. But many substrates that need coating have complex geometries and can have large variations in a vertical direction perpendicular to the substrate. For example, the substrate may be three-dimensional with a large area.

Substrates of complex geometries, for example, sun roofs, automotive lamps and reflectors, are coated by other methodologies than using a straight antenna coaxial line technology. Sun roofs, for example, may be made of polycarbonate as a replacement to glass components. However, polycarbonate is susceptible to scratching and degradation from UV light. Highly transparent protective coating is needed for both scratch resistance and UV light absorption.

One of the common coating methodologies utilizes liquid based lacquers to coat a large substrate of complex geometry. The lacquer-based coating can be sprayed on substrates such as polycarbonate and then thermally cured to provide a hard coating that also blocks UV light. Such a coating is typically in the range of 2-10 μm thick. The cost associated with this lacquer-based technology is so high that it limits applications.

Another coating method includes forming a soft UV blocking layer of benzyl phenon on a polycarbonate substrate. A hard organo-silicon coating can then be formed on the coated polycarbonate substrate by using plasma enhanced chemical vapor deposition (PECVD). The two-layer coating is normally 2-10 μm thick. Such an organo-silicon coating provides a much harder coating than the lacquer based system. However, the UV blocking layer beneath the organo-silicon coating is degraded from UV light attack over time. As a result of consumption of UV absorbers, the organo-silicon coating may shrink or crack after about 3000 to 5000 hours, which will shorten the lifetime of the scratch resistance coating.

For thin film deposition, it is often desirable to have a high deposition rate to form coatings on large substrates, and flexibility to control film properties. Higher deposition rates may be achieved by increasing plasma density or lowering the chamber pressure. For plasma etching, higher etching rates can be helpful for shortening processing cycle time. And a high plasma density source can be desirable.

In chemical vapor deposition (CVD), a film is formed by chemical reaction near the surface of a substrate. Typically, reactive gases are introduced into a processing chamber. The reactive gases may decompose from heat to form plasma. And a chemical reaction may occur on the surface of a substrate forming a film over the substrate. Volatile byproducts may be produced and transported away from the processing chamber. Examples of common CVD technologies include thermal CVD, low pressure CVD (LPCVD), plasma-enhanced CVD (PECVD), microwave plasma-assisted CVD, atmospheric pressure CVD, and the like. LPCVD uses thermal energy for reaction activation. The chamber pressure ranges from 0.1 to 1 torr, where temperature may be controlled to be around 600-900° C. by using multiple heaters. PECVD uses radio frequency (RF) plasma to transfer energy into the reactive gases and form radicals. This process allows a lower temperature than does LPCVD.

Using a microwave frequency sour can also provide an increase in plasma density. Microwave plasma PECVD inputs microwave power into the reactive gases at a microwave frequency, for example, commonly at 2.45 GHz, which is much higher than the RF frequency of 13.56 MHz. It is well known that at low frequencies, electromagnetic waves do not propagate in a plasma, but are instead reflected. However, at high frequencies such as at typical microwave frequencies, electromagnetic waves effectively allow direct heating of plasma electrons. As the microwaves input energy into the plasma, collisions can occur to ionize the plasma so that higher plasma density can be achieved. Typically, horns are used to inject the microwaves or a small stub antenna is placed in the vacuum chamber adjacent to the sputtering cathode for inputting the microwaves into the chamber. However, this technique does not provide a homogeneous assist to enhance plasma generation. It also does not provide enough plasma density to sustain its own discharge without the assistance of the sputtering cathode. Additionally, scale up of such systems for large area deposition is limited to a length on the order of 1 meter or less due to non-linearity.

### BRIEF SUMMARY

Embodiments of the invention includes a deposition system for dynamically coating surfaces with complex geometries. The system can include a processing chamber, a non-linear coaxial microwave source comprising an antenna within the processing chamber. The system can also include a substrate support member disposed inside the processing chamber that can hold a non-planar substrate, wherein the non-planar substrate can comprise a first contour along a first direction and a second contour along a second direction orthogonal to the first direction. The system can also include a carrier gas line for providing a flow of sputtering agents inside the processing chamber, and a feedstock gas line for providing a flow of precursor gases.

According to some embodiments, the deposition system for dynamic coating can include a stage coupled to the non-linear coaxial microwave source The stage can be configured to be movable relative to the non-planar substrate. In some embodiments, the deposition system for dynamic coating may include a stage coupled to the non-planar substrate that is configured to be movable relative to the coaxial microwave line source.

According to some embodiments, a deposition system for static coating includes a processing chamber, a substrate support member disposed inside the processing chamber, the substrate support member being configured to hold a non-planar substrate. The non-planar substrate can have a first contour along a first direction and/or a second contour along a second direction orthogonal to the first direction. The deposition system may include an array of curved coaxial microwave sources within the processing chamber. In some embodiments, each of the curved coaxial microwave sources can include a respective antenna and be formed in a respective shape. The curved coaxial microwave sources can be spaced along the second direction to cover the substrate. The deposition system can also include a carrier gas line for providing a flow of sputtering agents inside the processing chamber, and a feedstock gas line for providing a flow of precursor gases.

In some embodiments, a method for dynamically coating a non-planar substrate is disclosed. The method can include loading a non-planar substrate into a processing chamber. The non-planar substrate can have a first contour along a first direction and a second contour along a second direction orthogonal to the first direction. The method can also include providing a curved coaxial microwave source comprising an antenna and generating microwaves with the antenna. The method can also include flowing precursors into the processing chamber, forming a plasma from the precursors with the generated microwaves, and depositing coating over the non-planar substrate at a first position of the curved coaxial microwave source. Furthermore, the method can also include moving the curved coaxial microwave source to a second position along the second direction and forming coating over the substrate at the second position.

In some embodiments, a method for statically coating a non-planar substrate is disclosed. The method can include loading a non-planar substrate into a processing chamber. The non-planar substrate can have a first contour along a first direction and a second contour along a second direction orthogonal to the first direction. The method can also include providing an array of curved coaxial microwave sources, each of the curved coaxial microwave sources including a respective antenna. The curved coaxial microwave sources can be spaced along the second direction to cover the substrate. The method can also include generating microwaves with the curved coaxial microwave sources, flowing precursors into the processing chamber, forming plasma from the precursors with the generated microwaves, and/or depositing coating over the non-planar substrate.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings.

### BRIEF DESCRIPTION OF THE DRAWINGS

FIG. 1 shows a simplified diagram of a coaxial microwave-assisted chemical vapor deposition (CVD) system without a containment shield according to some embodiments of the invention.

FIG. 2 shows a simplified deposition system with a containment shield partially surrounding an antenna and having a generally circular cross section according to some embodiments of the invention.

FIG. 3 shows a schematic of a system including an array with curved coaxial microwave sources and a curved substrate according to some embodiments of the invention.

FIGS. 4A-4C illustrate embodiments of a curved coaxial microwave plasma source with recombination shielding that provides dynamic coating over a 2-dimensional curved substrate according to some embodiments of the invention.

FIGS. 5A-5B illustrate another embodiment of a curved coaxial microwave plasma source that provides dynamic coating over a 2-dimensional curved substrate according to some embodiments of the invention.

FIGS. 6A-6C illustrate one embodiment of an array with curved coaxial microwave sources that provides static coatings over a three-dimensional curved substrate according to some embodiments of the invention.

FIG. 7 is a flow diagram illustrating steps that may be used to dynamically form a film on a curved substrate according to some embodiments of the invention.

FIG. 8 is a flow diagram illustrating steps for static coating over a curved substrate according to some embodiments of the invention.

### DETAILED DESCRIPTION OF THE INVENTION

In accordance with embodiments of the invention, a substrates of complex geometries can be coated using curved coaxial microwave sources to match the complex geometries of the substrates. The coaxial microwave source can include an antenna that is a metallic waveguide with a microwave source. The coaxial microwave source may also include an isolation dielectric layer, such as quartz and a containment shield outside the antenna with or without the isolation dielectric layer. To accommodate large areas of a substrate, either the substrate is moved relative to the curved coaxial microwave source, or the curved coaxial microwave source is moved relative to the substrate. In some embodiments, either coating method can achieve coatings on 3 dimensional substrates.

Overview of Microwave PECVD

Microwave plasma deposition has been developed to achieve higher plasma densities (e.g. ˜10¹² ions/cm³) and higher deposition rates, as a result of improved power coupling and absorption at 2.45 GHz when compared to a typical radio frequency (RF) coupled plasma sources at 13.56 MHz. One drawback of using RF plasma is that a large portion of the input power is dropped across the plasma sheath (dark space). By using microwave plasma, a narrow plasma sheath can be formed and more power can be absorbed by the plasma for creation of radical and ion species. This can increase the plasma density with a narrow energy distribution by reducing collision broadening of the ion energy distribution.

Microwave plasma can have other advantages, such as lower ion energies with a narrow energy distribution. For instance, microwave plasma may have a lower ion energy, for example, of about 0.1-25 eV, which can lead to lower damage when compared to processes that uses RF plasma. In contrast, standard planar discharge could result in high ion energy of 100 eV with a broader ion energy distribution, which can lead to higher damage as the ion energy exceeds the binding energy for most materials of interest. This can inhibit the formation of high-quality crystalline thin films through the introduction of intrinsic defects. With low ion energy and/or narrow energy distribution, microwave plasma, for example, can help in surface modification and can improve coating properties.

In addition, a lower substrate temperature (e.g., lower than about 200° C. or about 100° C.) can be achieved as a result of increased plasma density at lower ion energy with narrow energy distribution. Such a lower temperature can allow better microcrystalline growth in kinetically limited conditions. Also, standard planar discharge without a magnetron can normally require a pressure greater than about 50 mtorr to maintain self-sustained discharge, as plasma becomes unstable at pressures lower than about 50 mtorr. The microwave plasma technology, described herein, however, can allow the pressure to range from about 10⁻⁶ torr to 1 atmospheric pressure. Thus, the processing window in temperature and pressure can be extended by using a microwave source.

In the past, one drawback associated with microwave source technology in the vacuum coating industry was the difficulty in maintaining homogeneity during scale up from small wafer processing to very large area processing. Microwave reactor designs in accordance with embodiments of the invention address these problems. Arrays of coaxial plasma linear sources have been developed to deposit substantially uniform coatings of ultra large area (e.g., greater than 1 m²) at high deposition rate to form dense and thick films (e.g., 5-10 μm thick).

An advanced pulsing technique has been developed to control the microwave power for generating plasma, and thus to control the plasma density and plasma temperature. This advanced pulsing technique may reduce the thermal load disposed over the substrate, as the average power may remain low. This feature can be relevant when the substrate has a low melting point or a low glass transition temperature, such as in the case of a polymer substrate. The advanced pulsing technique can allow for high power pulsing into plasma with off times in between pulses, which reduces the need for continuous heating of the substrate. Another aspect of the pulsing technique is significant improvement in plasma efficiency compared to continuous microwave power.

A Sample Deposition System

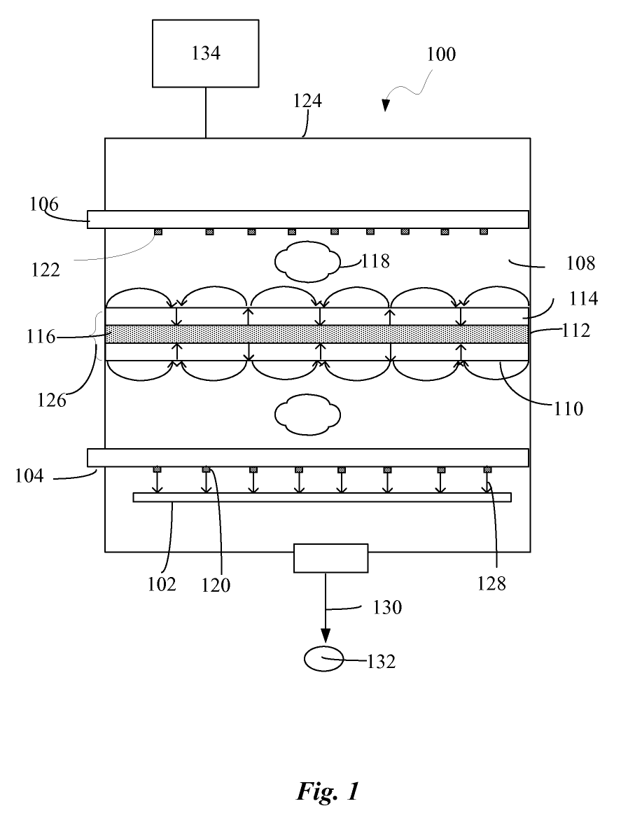

FIG. 1 shows a diagram of a coaxial microwave-assisted chemical vapor deposition (CVD) system 100 without a containment shield according to some embodiments of the invention. Multiple-step processes can be performed on a single substrate or wafer without removing the substrate from the chamber. The substrate may have a complex geometry that is either planar or non-planar. The major components of the system include, among others, a processing chamber 124 that receives precursors from feedstock gas line 104 and carrier gas line 106, a vacuum system 132, a coaxial microwave source 126, a substrate 102, and a controller 132.

The coaxial microwave source 126 includes, among others, an antenna 112, a microwave source 116, an outer envelope surrounding the antenna 112 made of dielectric material (e.g. quartz). The dielectric material, for example, can serve as a barrier between the vacuum pressure 108 and atmospheric pressure 114 inside the dielectric layer 110. The microwave source 116 can input the microwave into the antenna 112. The atmospheric pressure can be used to cool the antenna 112. Electromagnetic waves are radiated into the chamber 124 through the dielectric layer 110. Plasma 118 may be formed over the surface of the dielectric material. In a some embodiments, the coaxial microwave source 126 may be curved. The coaxial microwave source 126 may be an array of the coaxial microwave sources.

In some embodiments, the feedstock gas line 104 may be located below the coaxial microwave source 126 and above the substrate 102 which is near the bottom of the processing chamber 124. in some embodiments, the carrier gas line 106 may be located above the coaxial microwave source 126 and near the top of the processing chamber 124. Through the perforated holes 120 and 122, the precursor gases and carrier gases can flow into the processing chamber 124. The precursor gases are vented toward the substrate 102 (as indicated by arrows 128), where they may be uniformly distributed radically across the substrate surface, typically in a laminar flow. After deposition is completed, exhaust gases exit the processing chamber 124 by using vacuum pump 132 through exhaust line 130.

The controller 134 can controls activities and/or operating parameters of the deposition system, such as the timing, mixture of gases, chamber pressure, chamber temperature, pulse modulation, microwave power levels, and other parameters of a particular process.

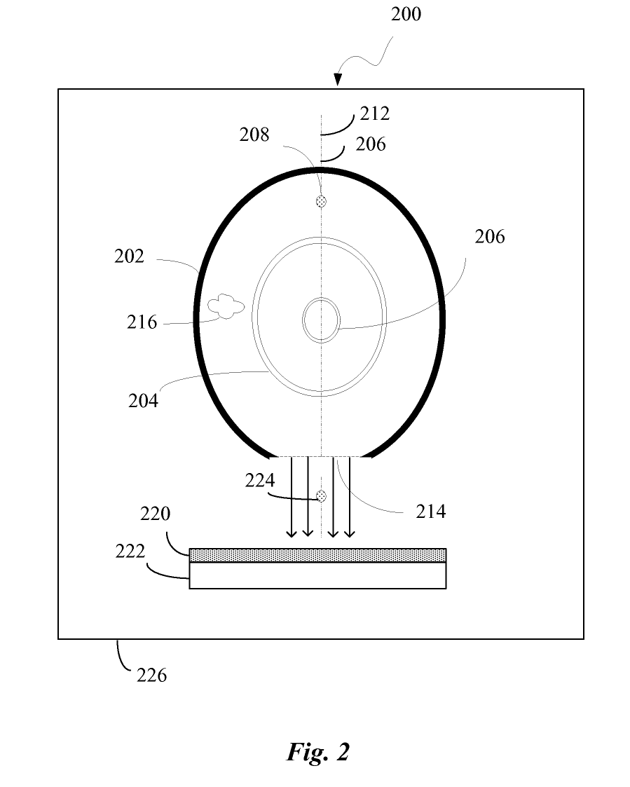

FIG. 2 shows deposition system 200 with a containment shield 202 partially surrounding an antenna with a generally circular cross section. The antenna can include a waveguide 206 and a dielectric tube 204 as a pressure isolation barrier. Air or nitrogen can be filled in the space between the dielectric tube 204 and waveguide 206 for cooling the antenna. The first pressure inside the dielectric tube 204 may be one atmospheric pressure. The circular containment shield 202 can be placed outside the dielectric tube 204 for containing plasma 216 that is formed from sputtering agents coming from a carrier gas line 208 located on a centerline 212. The plasma 216 can come through an aperture 214 near the bottom of the containment shield 202 to collide with reactive precursors from a feedstock gas line 224. Radical species generated by the plasma 216 disassociate the reactive precursors to form a film on a substrate 220 that is held by a substrate support member 222. The second pressure inside the containment shield 202 may be higher than the third pressure inside a processing chamber 226. The dielectric tube 204 may comprise a quartz to form a pressure isolation barrier and still allow microwaves to leak through.

For illustration purpose, only circular containment shield is shown. Other shapes of containment shield may be used. Details are included in U.S. patent application Ser. No. 12/238,664, entitled “Microwave Plasma Containment Shield Shaping” by Michael Stowell, the entire contents of which are incorporated herein by reference for all purposes.

A feedstock gas line 224 can be located outside the containment shield 202 and proximate the substrate 220 to be coated as shown in FIG. 2. The feedstock gas line 224, for example, can be placed here because the radical density may be so high that some of the radicals may deposit over the inner wall of the containment shield 202. The feedstock gas can provide one or more of the atoms or molecules to produce desired dielectric coatings such as SiO₂, where a silicon containing gas, for example, hexamethyldisiloxane (HMDSO), can be left in the feedstock gas line 224. The position of the feedstock gas line may be adjusted to control the film chemistry. There are also exceptional cases where a reactive gas may be included among the carrier gases, such as ammonia that may be used to form nitride.

The containment shield 202 may comprise a dielectric material, for example, Al₂O₃, quartz, or pyrex. A pressure difference may be present between the internal pressure of the containment shield and the external pressure of the containment shield, with the internal pressure being higher than the external pressure. This allows more processing flexibility than without using the containment shield. With increased pressure inside the containment shield, plasma species or radicals may have more collisions and thus higher radical density. With lower pressure outside the containment shield, the chamber pressure may be lower. As a result of lower chamber pressure, the mean free path can increase for plasma species or radicals and thus deposition rates can be increased.

Furthermore, the plasma containment shield may help increase radical density and/or can help form a homogeneous plasma. The shield can help increase the collisions among the radicals by confining the radicals within the containment shield without losing the radical species. As a result of using the plasma containment shield, radical density can be increased and homogeneity is improved, particularly in radical direction.

In addition, by using a containment shield, the volume of the gas inside the plasma containment shield may be more fully ionized and thus may produce more radicals so that ionization efficiency may be improved. For example, the inventors performed experimental tests to demonstrate that the ionization efficiency may be improved from 65% to 95% by using a plasma containment shield.

Film properties requirements can be achieved by varying process conditions during deposition, including the power levels, pulsing frequency and duty cycle of the source. To achieve the required film properties the structure and structural content of the deposited film may be controlled; for example, by varying the radical species content, among other processing parameters. The radical density is controlled primarily by the average and peak power levels into the plasma discharge.

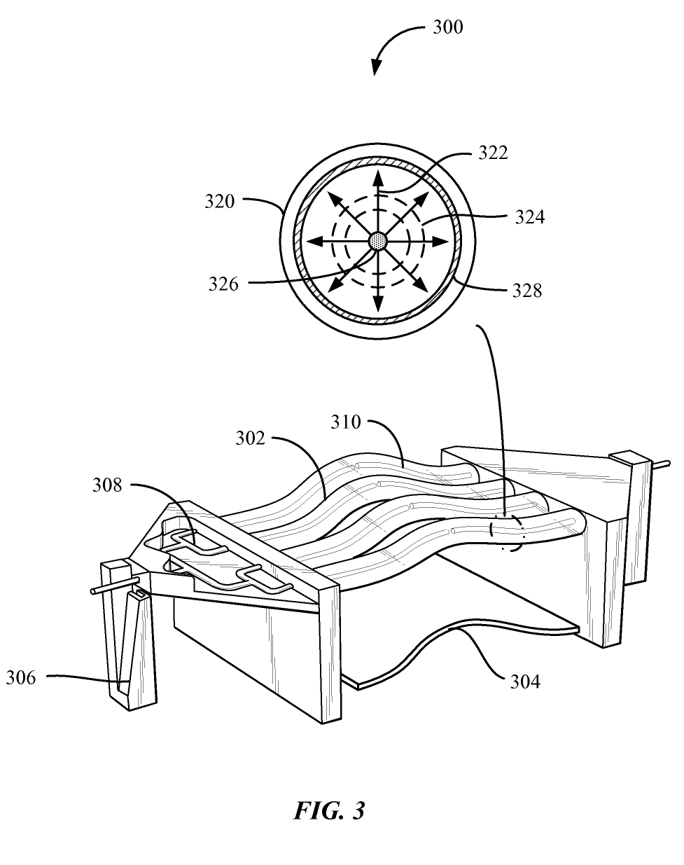

Multiple antenna and plasma pipes may be used in this fashion to produce a large array for static or dynamic coatings. FIG. 3 shows a schematic of a simplified system including an array 302 comprising 4 curved coaxial microwave sources 310, a curved substrate 304, a cascade coaxial power provider 308, and an impedance matched rectangular waveguide 306. In the curved coaxial microwave source 310, microwave power is radiated into a processing chamber in a transversal electromagnetic (TEM) wave mode. A curved tube can be made of dielectric material, such as quartz or alumina having high heat resistance and a low dielectric loss, which can act as the interface between the waveguide having atmospheric pressure and the vacuum chamber.

A cross sectional view of a coaxial microwave source 300 can illustrate the cross section of a curved conductor (e.g., antenna) 326. This curved conductor 326 can be used, for example, to radiate microwaves at a frequency of 2.45 GHz. The radial lines represent an electric field 322 and the circles represent a magnetic field 324. The microwaves can propagate through the air to the curved dielectric layer 328 and then leak through the dielectric layer 328 to form an outer plasma conductor 320 outside the dielectric layer 328. Such a wave sustained near the coaxial microwave source can be a surface wave. The microwaves can propagate along the curved conductor 326 and go through a high attenuation by converting electromagnetic energy into plasma energy. Another configuration that may be used is without quartz or alumina outside the microwave source.

The curved antenna 326 can be surrounded by a curved dielectric layer 328 forming a pressure isolation barrier between the atmospheric pressure of the antenna cooling from the internal lower pressure of the processing chamber. Electromagnetic radiation can radiate into the processing chamber through the dielectric envelope, and plasma is formed on the outside surface of the quartz tube. A support gas pipe provides gases used to form plasma and produce radicalized species used in the deposition process. The support gas may include more than one gas for this purpose. The feedstock gas can be the precursor containing one or more of the atoms and molecules necessary to produce the desired film properties. This feedstock gas pipe can be located, for example, near the surface of the substrate to be coated. The position of this pipe may be tuned to provide desired film chemistry.

The plasma produces radicalized species that reacts with the feedstock gas inside the processing chamber, near the surface of the substrate. These radicals, for example, can recombine in the gas volume and become unusable to produce required fractional components and to form desired films. Typically, the radicals may be pumped out of the system and do not contribute to forming the desired films. The plasma produced radical species can have multiple loss mechanisms, including, among others, recombination, pumping, fractionalization of precursor gas, inclusion into the growing film. The gas ionization efficiency or plasma efficiency is typically not 100%. Hence, reducing the loss of radicals and or increasing the amount of radicals produced for a given power level can be beneficial in growing films.

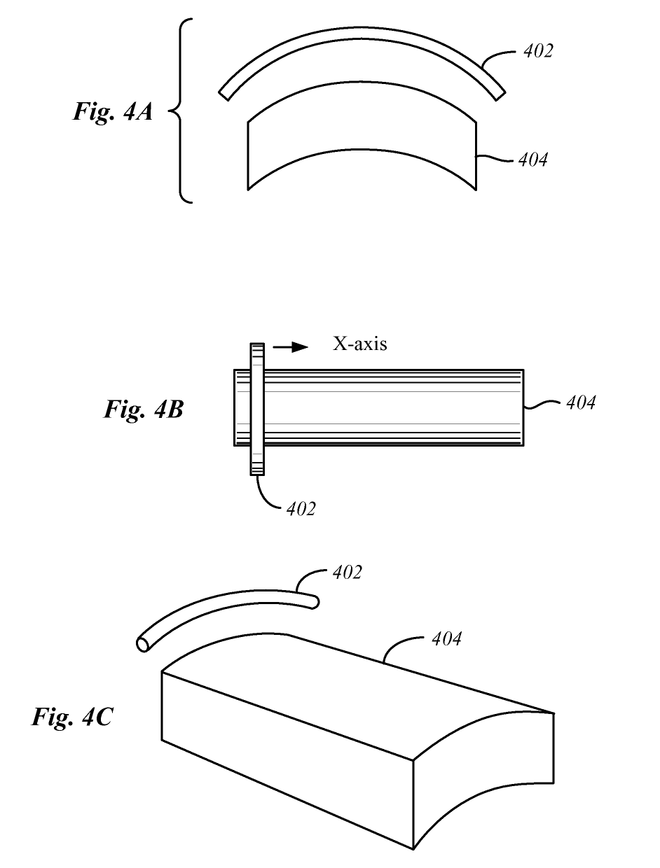

FIGS. 4A-4C illustrate one embodiment of a curved coaxial microwave plasma source with recombination shielding to provide dynamic coating over a large curved substrate, such as a car sun roof. As illustrated in FIG. 4A, a curvature of the coaxial microwave plasma source 402 may be substantially matched with shape of the curved substrate 404 such that the distance between the microwave source 402 and the substrate 404 remains substantially constant in a cross sectional view. FIG. 4B shows a top view of the curved substrate 404 that has a dimension remaining unchanged along a horizontal direction as shown by x-axis. Therefore, a homogeneous coating would be obtained over a large area by moving the curved coaxial microwave plasma source 402 along the x-axis relative to the substrate 404. FIG. 4C illustrates a three-dimensional view of the substrate having a curved contour in a sectional view perpendicular to the x-axis.

The curved coaxial microwave plasma source 402 may also be moved in the vertical axis to be closer or away from the substrate, depending upon film chemistry. For example, a typical spacing between the microwave source and substrate may be 15 cm for depositing silicon oxide, but may be approximately 5-15 cm for depositing magnesium oxide over the substrate.

In some embodiments of the invention, the coaxial microwave source may be moved along a horizontal direction perpendicular to the x-axis. This can be done, for example, to coat a large substrate. For example, if the substrate has a dimension of 16 feet long, 3-4 feet wide and 3-4 feet tall, the coaxial microwave source may need to be moved along the length of the substrate. However, if the substrate has a dimension of 16 feet long, 16 feet wide and 3-4 feet tall, the coaxial microwave source may need to be moved along both the length and the width of the substrate in order to form coatings over the large substrate. Large substrates can include, for example, automotive parts, aircraft parts, maritime parts, etc.

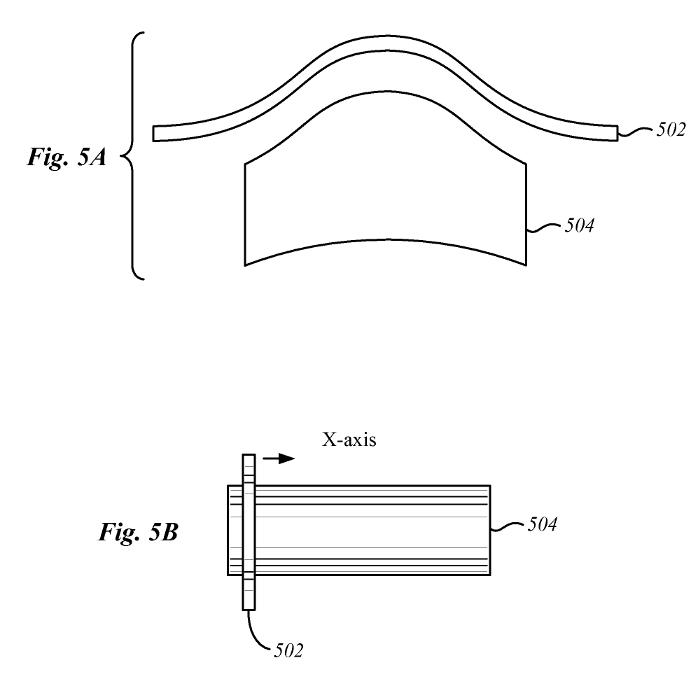

FIGS. 5A-5B illustrate another embodiment of a curved coaxial microwave plasma source that can provide dynamic coatings over a large curved substrate. As illustrated, a curvature of the coaxial microwave plasma source 502 may be substantially matched with the shape of the curved substrate 504 such that the distance between the microwave source 502 and the curved substrate 504 remains substantially constant in a cross sectional view. The geometries of this substrate and the microwave source are different from that shown in FIGS. 4A-C. However, curvatures in both FIG. 5A and FIG. 4A are smooth, such that a first derivative of the curvature would show continuous curvatures. Such a smooth curvature would be beneficial to forming a homogeneous coating over the substrate. Deposition can occur on substrates with various curvatures.

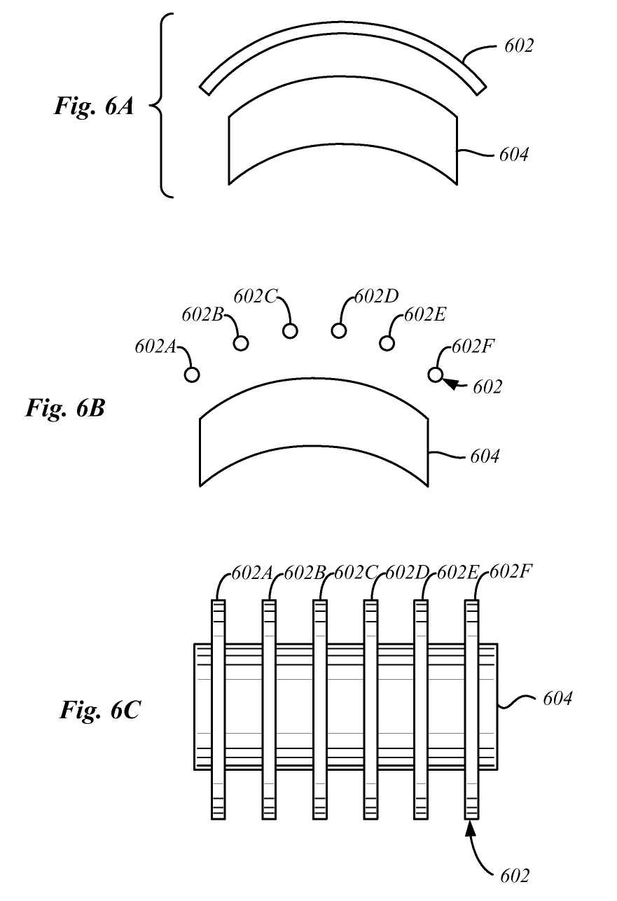

For illustration purposes, FIGS. 6A-6C show an array of 6 curved coaxial microwave sources for providing static coatings over a three-Dimensional substrate. FIGS. 6A-6B are a sectional view and a front view of the arrangement of curved coaxial microwave source 602 and curved substrate 604, respectively. Note that the curvatures of the coaxial microwave source 602A-F are roughly matched with the curvatures of the substrate 604 at positions A-F, respectively. The curvatures of the coaxial microwave plasma sources 602A-F may vary from the corresponding positions A-F on the substrate. Each of the curved coaxial microwave plasma sources 602A-F may have a distance between each of the curved coaxial microwave sources and the substrate. The distance may vary from the positions A-F of the sources 602A-F such that the array of 6 curved coaxial microwave sources provides coverage of surface area of a three-dimensional substrate of any complex geometry. As illustrated in FIG. 6B, the positions of the curved coaxial microwave plasma sources 602A-F are arranged on a curve which approximately matches with the curvature of the substrate 604. FIG. 6C shows a top view of the array of the curved coaxial microwave sources and the substrate. Note that the coaxial microwave sources are spaced out to cover the substrate. The distance between each two neighboring sources of 602A-F may be half wavelength of the microwave. The length of each coaxial microwave source may be up to 3 m in some embodiments.

Substrate preheating treatment can be achieved by utilizing many techniques and heater arrangements. It is common to heat the substrate using a direct heater such as a resistor heating plate in thin film deposition processes. By using a direct heating plate, the substrate temperature may be heated up to approximately 700° C. With microwave-assisted CVD, the substrate temperature may be lowered to below 200° C. In the case of lower substrate temperature, indirect heating sources may be used, such as a resistor heating source, a lamp, or a flash heater. Flash heaters have been developed to significantly reduce cycle times and increase productivity in rapid thermal processing. Flash heaters are used in many applications, such as repairing damage and annealing surface and so on.

One of the challenges in thin film deposition on plastic substrates is the difficulty in maintaining structural integrity of plastic substrates. Plastics have a much lower softening temperature, such as melting point or glass transition temperature, than glasses or ceramics. When a plastic substrate is heated near the softening temperature prior to thin film deposition or etching, the plastic substrate often reaches the melting point or glass transition temperature with the additional heat generated from the thin film deposition process. Therefore, the plastic substrate may experience structural distortion as a result of overheating during the thin film deposition or etching process.

A source of IR radiation, such as an infrared heater, can heat a plastic substrate in a fast fashion in a processing chamber, where the processing chamber is configured to preheat the plastic substrate and to perform thin film deposition, such as chemical vapor deposition (CVD). One advantage of using the source of IR radiation is to preheat only the surface of the plastic substrate while the core of the plastic substrate remains substantially unheated and the structure of the plastic substrate may remain unchanged. Meanwhile, the surface properties of the plastic substrate may be modified after the preheating treatment.

The source of IR radiation can be selected at a wavelength that substantially matches the absorption wavelength of the plastic substrate. This can optimize the energy absorption of the surface of the plastic substrate. Another aspect of the fast preheating treatment is that the source of IR radiation can be powered on continuously while the plastic substrate moves through the heat flux zone generated by the source of IR radiation at a controllable speed. Such a preheating treatment allows the plastic substrate to be heated substantially uniform in a few seconds. The plastic substrate may be preheated near a critical temperature that allows a change in surface morphology or surface structure to occur. Examples are included in U.S. patent application Ser. No. 12/077,375, entitled “Surface Preheating Treatment of Plastic Substrate” by Michael W. Stowell et al, the entire contents of which are incorporated herein by reference for all purposes.

The source of IR radiation may be configured to move relative to the substrate such that the movement of the source of IR radiation corresponds to the movement of the coaxial microwave source to provide local heating of a large substrate and dynamic coating over the large substrate.

Fabrication of Curved Coaxial Microwave Sources

According to one embodiment of the present invention, the antenna includes a conductive waveguide. The conductive waveguide may experience thermal distortion due to heating of the antenna in radiating electromagnetic radiation. Material selection of the waveguide may vary with the need to have both good electrical conductivity and good thermal resistance to warp or distortion. In a specific embodiment, the waveguide may be made of titanium coated with gold, where titanium provides good thermal resistance while gold is a very good conductor. In another embodiment, the waveguide may be made of aluminum, stainless steel, copper coated with silver. Different materials may have various electrical conductivity, various resistance to thermal stress or thermal distortion, and cost variation associated with material and fabrication.

For example, the waveguide may have an outer diameter of a few millimeters, such as 6 mm with a wall thickness of 1 to 1.5 mm. The isolation barrier tube may have a larger diameter than the waveguide, for example, an outer diameter of 38 mm with a wall thickness of 3 mm. There may be different ways of making the dielectric tube. In a specific embodiment, the isolation barrier tube may be fabricated by using a sheet of glass having a desired wall thickness. The sheet of glass may be heated by using a flame heater to bend and wrap around a mandrel to form a curved tube of any desired shape. The mandrel may be a metal that can be formed to have the desired shape.

The containment shield may have a relatively larger diameter to provide space for containing plasma inside. In some embodiments of the invention, an outer diameter of the containment shield may be 6 inches with a wall thickness of approximately 0.2 inches. The containment shield may be made of quartz, alumina or a borosilicate glass with low coefficient of thermal expansion such as Pyrex. One of the common fabricating methods is to cast the containment shield in a mold to obtain any desired shape. The containment shield may be further annealed to increase density to achieve required properties or performance.

The waveguide, quartz tube, and containment shield may be integrated together by common technologies known in the art after each of the component is fabricated to the desired shape which matches with any desired shape of the substrate.

Deposition Process

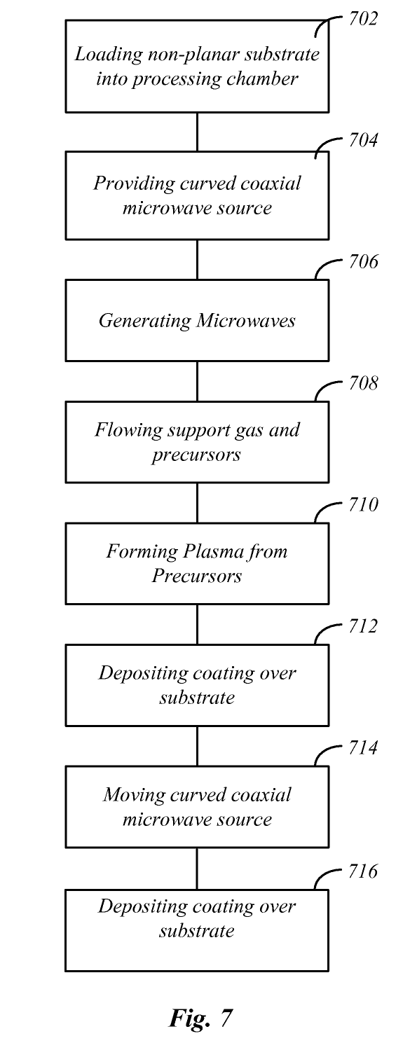

For purposes of illustration, FIG. 7 provides a flow diagram of a process that may be used to form a film on a curved substrate in a dynamic coating according to some embodiments of the invention. The process begins with loading a curved substrate into a processing chamber at block 702. The substrate may have smooth curvature, for example, as illustrated in FIGS. 4A-C or FIGS. 5A-5C. Next, the process can provide a curved coaxial microwave source to the processing chamber at block 704. The curved coaxial microwave source can be configured to move relative to the substrate, or the substrate is configured to move relative to the curved coaxial microwave source within the processing chamber. The process followed by generating a microwave with the microwave source at block 706.

Film deposition can be initiated by flowing gases, such as sputtering agents or reactive precursors at block 708. For deposition of SiO₂, such precursor gases may include a silicon-containing precursor such as hexamthyldisiloxane (HMDSO) and oxidizing precursor such as O₂. For deposition of SiOₓN_{y}, such precursor gases may include a silicon-containing precursor such as hexmethyldislanzane (HMDS), a nitrogen-containing precursor such as ammonia (NH₃), and an oxidizing precursor. For deposition of ZnO, such precursor gases may include a zinc-containing precursor such as diethylzinc (DEZ), and an oxidizing precursor such as oxygen (O₂), ozone (O₃) or mixtures thereof. The reactive precursors may flow through separate lines to prevent them from reacting prematurely before reaching the substrate. Alternatively, the reactive precursors may be mixed to flow through the same line.

The carrier gases may act as a sputtering agent. For example, the carrier gas may be provided with a flow of H₂ or with a flow of inert gas, including a flow of He or even a flow of a heavier inert gas such as Ar. The level of sputtering provided by the different carrier gases is inversely related to their atomic mass. Flow may sometimes be provided using multiple gases, such as by providing both a flow of H₂ and a flow of He, which mix in the processing chamber. Alternatively, multiple gases may sometimes be used to provide the carrier gases, such as when a flow of mixed H₂/He is provided into the processing chamber.

As indicated at block 710, a plasma is formed from the gases by microwave at a frequency ranging from 1 GHz to 10 GHz, for example, commonly at 2.45 GHz (a wavelength of 12.24 cm). In addition, a higher frequency of 5.8 GHz is often used when power requirement is not as critical. The benefit of using a higher frequency source is that it has smaller size (about half size) of the lower frequency source of 2.45 GHz. In some embodiments, the plasma may be a high-density plasma having an ion density that exceeds 10¹² ions/cm³. The process continues by depositing dynamic coating over the curved substrate at block 712 and moving the coaxial microwave plasma source to a next position at block 714. Assuming that a width of the coaxial microwave source is longer than a width of the substrate, the movement of the source is along a longitudinal direction perpendicular to the width of the substrate. The process proceeds by further depositing coating over the substrate at the next position at block 716.

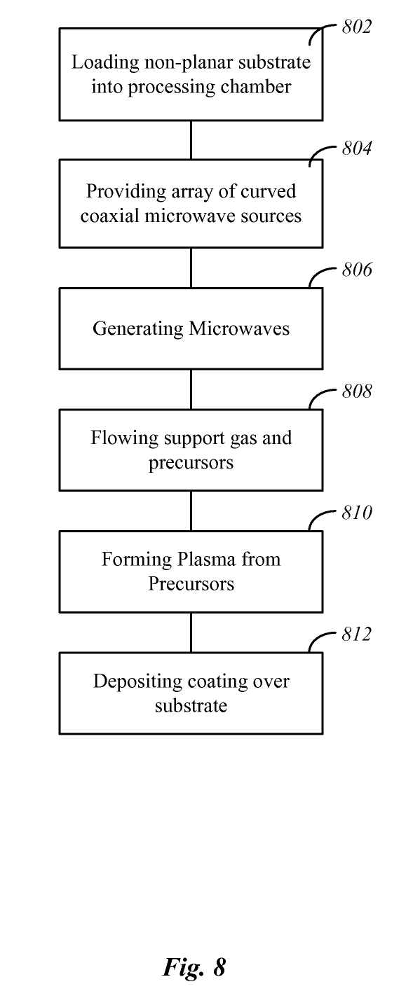

FIG. 8 is a flow diagram illustrating steps for static coating over a curved substrate according to some embodiments of the invention. Similar to the dynamic coating over a curved substrate, the process can start with loading a curved three-dimensional substrate into a processing chamber at block 802. The process can also provide an array of curved antenna into the processing chamber at block 804 and can generate microwaves at block 806. The array of curved antenna is arranged such that a homogeneous static coating may be formed over the curved three-dimensional substrate, for example, as shown in FIGS. 6A-6C. Again, like the dynamic coating process illustrated in FIG. 7, the process can continue by flowing precursors into the processing chamber at block 808 and forming plasma from the precursors with the generated microwaves at block 810. The process proceeds by depositing static coating over the curved substrate at block 812.

While the above is a complete description of specific embodiments of the present invention, various modifications, variations and alternatives may be employed. Examples of the possible parameters to be varied include but are not limited to the temperature of deposition, the pressure of deposition, and the flow rate of precursors and carrier gases.

Those of ordinary skill in the art will realize that specific parameters can vary for different processing chambers and different processing conditions, without departing from the spirit of the invention. Other variations, among others, including shapes or geometry of curved coaxial microwave sources or non-planar substrates, configuration of the array of curved coaxial microwave sources relative to the substrates, types of source of IR radiation, configuration of moving stages for either the sources or substrate, will also be apparent to persons of skill in the art. These equivalents and alternative are intended to be included within the scope of the present invention. Therefore, the scope of this invention should not be limited to the embodiments described, but should instead be defined by the following claims.

What is claimed is:

1. A deposition system comprising:
a processing chamber;
a non-linear coaxial microwave source including an antenna and being disposed within the processing chamber;
a substrate support member disposed within the processing chamber, the substrate support member being configured to hold a non-planar substrate, wherein the non-planar substrate comprises a first contour along a first direction and a second contour along a second direction orthogonal to the first direction, wherein at least one of the first contour and the second contour are nonlinear;
a carrier gas line disposed at least partially within the processing chamber; and
a feedstock gas line for providing a flow of precursor gases.

2. The deposition system of claim 1, wherein the non-linear coaxial microwave source is shaped to match the first contour of the non-planar substrate such that a distance between the non-linear coaxial microwave source and the first contour of the non-planar substrate remains substantially a constant along the first direction.

3. The deposition system of claim 1, the deposition system further comprises a stage coupled to the non-linear coaxial microwave source, wherein the stage is configured to be movable relative to the non-planar substrate.

4. The deposition system of claim 1, the deposition system further comprises a stage coupled to the non-planar substrate, wherein the stage is configured to be movable relative to the coaxial microwave line source.

5. The deposition system of claim 1, wherein the antenna comprises:
a non-linear metallic waveguide for converting an electromagnetic wave into a surface wave and radiating the surface wave in a radial direction;
a non-linear dielectric tube, the dielectric tube surrounding the metallic waveguide and being substantially coaxial with the metallic waveguide, wherein the non-linear metallic waveguide and the non-linear dielectric tube are shaped to substantially match with the first contour of the non-planar substrate.

6. The deposition system of claim 5, wherein the waveguide comprises a first metal coated with a second metal.

7. The deposition system of claim 6, wherein the first metal comprises a material selected from the group consisting of titanium, aluminum, stainless steel and copper.

8. The deposition system of claim 5, wherein the second metal comprises a material selected from the group consisting of gold and silver.

9. The deposition system of claim 5, wherein the dielectric tube comprises quartz.

10. The deposition system of claim 1, wherein the non-linear coaxial microwave source comprises a non-linear containment shield outside the antenna, the containment shield being substantially coaxial with the antenna, wherein the containment shield is shaped to match with the first contour of the non-planar substrate.

11. The deposition system of claim 10, wherein the containment shield comprises quartz or alumina.

12. The deposition system of claim 1, the deposition system further comprises an Infrared radiation heater or a lamp being disposed to heat the non-planar substrate.

13. The deposition system of claim 1, wherein the non-planar substrate has a substantially constant thickness.

14. The deposition system of claim 1, wherein the non-planar substrate comprises a plastic or a composite.

15. A deposition system for static coating comprises:
a processing chamber;
a substrate support member disposed inside the processing chamber, the substrate support member being configured to hold a non-planar substrate, wherein the non-planar substrate comprises a first contour along a first direction and a second contour along a second direction orthogonal to the first direction;
an array of curved coaxial microwave sources within the processing chamber, wherein:
each of the curved coaxial microwave sources comprises a respective antenna and a respective shape;
the curved coaxial microwave sources are spaced along the second direction to cover the substrate;
a carrier gas line for providing a flow of sputtering agents inside the processing chamber; and
a feedstock gas line for providing a flow of precursor gases.

16. The deposition system of claim 15, wherein at least one of the coaxial microwave sources has a curvature substantially matched to the first contour at a position of one of the coaxial microwave sources such that a distance between the one of the non-linear coaxial microwave sources and the non-planar substrate at the position remains substantially a constant.

17. The deposition system of claim 15, wherein different ones of the respective shapes are different from one another.

18. The deposition system of claim 15, the deposition system further comprises an Infrared radiation heater or a lamp disposed to heat the non-planar substrate.

19. The deposition system of claim 15, wherein each respective antenna comprises:
a non-linear metallic waveguide for converting an electromagnetic wave into a surface wave and radiating the surface wave in a radial direction;
a non-linear dielectric tube, the dielectric tube surrounding the metallic waveguide and being substantially coaxial with the metallic waveguide, wherein the non-linear metallic waveguide and the non-linear dielectric tube are shaped to substantially match with the first contour of the non-planar substrate.

20. The deposition system of claim 15, wherein each coaxial microwave source comprises a respective containment shield outside the respective antenna, the respective containment shield being substantially coaxial with the respective antenna.

21. The deposition system of claim 20, wherein the waveguide comprises a first metal coated with a second metal.

22. The deposition system of claim 21, wherein the first metal comprises a material selected from the group consisting of titanium, aluminum, stainless steel and copper.

23. The deposition system of claim 21, wherein the second metal comprises a material selected from the group consisting of gold and silver.

24. The deposition system of claim 20, wherein the dielectric tube comprises quartz.

25. The deposition system of claim 20, wherein the containment shield comprises quartz or alumina.

26. The deposition system of claim 15, wherein the non-planar substrate comprises plastics or composite.

27. A method of dynamic coating over a non-planar substrate comprising:
loading a non-planar substrate into a processing chamber, the non-planar substrate having a first contour along a first direction and a second contour along a second direction orthogonal to the first direction;
providing a curved coaxial microwave source comprising an antenna;
generating microwaves with the antenna;
flowing precursors into the processing chamber;
forming plasma from the precursors with the generated microwaves;
depositing coating over the non-planar substrate at a first position of the curved coaxial microwave source;
moving the curved coaxial microwave source to a second position of the curved coaxial microwave source along the second direction; and
forming coating over the substrate at the second position.

28. The method of dynamic coating of claim 27 further comprising heating the non-planar substrate using at least one Infrared heater at a first location to match the first position of the curved coaxial microwave source;
moving the Infrared heater to a second location to match the second position of the curved coaxial microwave source; and
heating the substrate with the Infrared heater at the second location.

29. The method of dynamic coating of claim 27, wherein the curved coaxial microwave source has a curvature substantially matched to the first contour of the non-planar substrate such that a distance between the non-linear coaxial microwave source and the non-planar substrate remains substantially a constant along the first direction.

30. The method of dynamic coating of claim 27, further comprising moving a stage coupled to the non-linear coaxial microwave source relative to the non-planar substrate.

31. The method of dynamic coating of claim 27, further comprising moving a stage coupled to the non-planar substrate relative to the coaxial microwave line source.

32. The method of dynamic coating of claim 27, wherein the non-planar substrate comprises plastics.

33. A method of static coating over a non-planar substrate comprising
loading a non-planar substrate into a processing chamber, the non-planar substrate having a first contour along a first direction and a second contour along a second direction orthogonal to the first direction;
providing an array of curved coaxial microwave sources, each of the curved coaxial microwave sources comprising a respective antenna, wherein the curved coaxial microwave sources are spaced along the second direction to cover the substrate;
generating microwaves with the curved coaxial microwave sources;
flowing precursors into the processing chamber;
forming plasma from the precursors with the generated microwaves; and
depositing coating over the non-planar substrate.

34. The method of static coating of claim 33 further comprising heating the non-planar substrate using a plurality of Infrared heaters, wherein the Infrared heaters are configured to provide the substrate substantially uniform heating.

35. The method of static coating of claim 33, wherein the coaxial microwave source has a curvature substantially matched to the first contour at a position of the one of the curved coaxial microwave sources such that a distance between the one of the curved coaxial source and the non-planar substrate remains substantially a constant.
